(19) United States
(12) Patent Application Publication
(10) Pub. No.: US 2003/0001228 A1
(43) Pub. Date: Jan. 2, 2003

(54) Antistatic contact for a polycrystalline silicon line

(75) Inventors: Philippe Boivin, Venelles (FR); Francesco La Rosa, Rousset (FR)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: STMicroelectronics S.A., Montrouge (FR)

(21) Appl. No.: 10/165,051

(22) Filed: Jun. 7, 2002

(30) Foreign Application Priority Data
Jul. 2, 2001 (FR) 0108776

(51) Int. Cl. H01L 29/00

(52) U.S. Cl. 257/518

(57) ABSTRACT

An integrated circuit on a silicon substrate includes at least one polysilicon line and at least one antistatic contact connecting the polysilicon line to the silicon substrate. The antistatic contact includes a thin oxide layer between the polysilicon line and the silicon substrate. The thin oxide layer is of a sufficiently small thickness so that a current flows across it by the tunnel effect when the polysilicon line is brought, relatively to the substrate, to a voltage greater or less than determined thresholds.

### FIELD OF THE INVENTION

The present invention relates to integrated circuits, and more specifically, to an integrated circuit comprising polysilicon (polycrystalline silicon) conducting lines.

### BACKGROUND OF THE INVENTION

In CMOS integrated circuits, polysilicon is used for forming MOS transistor gates and for forming lines for interconnecting MOS transistors. The various conducting lines connecting transistors with floating gates of an electrically programmable and erasable memory, notably the word lines and gate control lines (EEPROM memories), are generally polysilicon, for example.

To produce such lines in polysilicon, a polysilicon layer is deposited on the surface of a silicon wafer with an oxide layer therebetween. It is then etched according to the desired topography or layout. As the polysilicon lines are electrically insulated from the silicon substrate by the oxide layer, they each form the equivalent of a capacitor plate with the other plate being formed by the substrate.

Current manufacturing processes for integrated circuits comprise steps which induce electrostatic charges in the polysilicon lines, notably steps requiring the use of plasma, as in plasma etching and dopant implantations. Thus, the polysilicon lines are often found to be at a high electrical potential because of a build-up of electrostatic charges, which may be several tens of volts. Such an electrical potential induces a strong electric field in the regions where the oxide layer is the thinnest, notably the oxide regions for the MOS transistor gate. This phenomenon may lead to a deterioration of MOS transistor performance, even to a breakdown of the gate oxide.

Providing antistatic contacts for protecting the polysilicon lines against the build-up of electrostatic charges is a known approach to this problem. The term antistatic contact refers to any means providing a preferential conduction path for removing these charges. This may be in the form of a weak current which may flow in the direction from the polysilicon to the substrate, or vice versa, without affecting the operation of an integrated circuit.

FIG. 1 is a partial sectional view of an integrated circuit 10 being manufactured, and it illustrates a conventional structure for an antistatic contact 11, also called a buried contact. A P-type silicon substrate 1 is shown on which field oxide regions 2 have been formed which delimit an active region A for receiving the MOS transistor gates and an inactive region B. The field oxide regions 2 and the substrate 1 are covered with an oxide layer 3 forming a gate oxide 3-1 in the active region, and a polysilicon layer 4 forming a gate material 4-1 in the active region.

Before depositing the oxide layer 3, an N+ doped region 5 has been implanted in the substrate at area B. Before depositing the polysilicon layer 4, an aperture 6 is provided in the oxide layer 3 above the doped region 5. Thus, when the polysilicon layer 4 is deposited, the latter is in contact with the region 5 via the aperture 6, which forms an antistatic contact 11. As region 5 is doped as N+, the polysilicon layer 4 is electrically connected to the potential of the substrate 1 via an NP junction forming a diode. Such an NP junction prevents the polysilicon from being negatively charged with respect to the substrate 1, and in the case of a positive charge, provides a passage for a leakage current which is sufficient for preventing a breakdown of the oxide layer in the active region.

When the integrated circuit 10 is finished and operational, the polysilicon layer 4 receives a positive voltage, the substrate is grounded, and the PN junction is reverse biased and its presence is not detrimental to the operation of the integrated circuit. Of course, a PN junction may be provided instead of the NP junction if the polysilicon layer is expected to receive a negative voltage with respect to the substrate when the integrated circuit is operational.

Although the combination of such an antistatic contact 11 and an NP or PN junction satisfactorily removes electrostatic charges, providing such an antistatic contact in an integrated circuit leads to different constraints or drawbacks in terms of technology. A first drawback is that the polysilicon layer 4 should have a doping of the same type as the region 5, so as not to form with region 5 a parasitic PN junction. It is therefore not possible to provide a doping of another type, even when such doping is desired.

Another drawback is that the dopants in the polysilicon layer 4 diffuse into the substrate during the annealing phases and are added to the dopants present in region 5. Thus, a “pollution” of the substrate occurs by diffusion of dopants in the vicinity of the antistatic contact 11. This means that the location to be reserved for an antistatic contact should take into account the diffusion of dopants in the vicinity of the antistatic contact, and that the actual size of the antistatic contact in terms of reserved silicon surface is not insignificant.

Finally, within the framework of producing an integrated circuit comprising floating gate transistors, achieving a direct contact between the polysilicon and the substrate (at the doped region 5) requires different processing steps which are added to those of the standard manufacturing processes. These processing steps have the purpose of removing, at the bottom of the aperture 6, a tunnel oxide layer formed on the integrated circuit before producing the floating gate transistors.

As the tunnel oxide layer is formed by growing an oxide, it is inevitably found at the bottom of the aperture 6 since the growing process is not selective, and therefore, it should subsequently be removed. This removal step is complex because a resin mask cannot be directly deposited on the tunnel oxide layer. First, a polysilicon layer should be deposited and should be etched, then the etched polysilicon layer is used as an etching mask for the tunnel oxide present at the bottom of the aperture 6.

### SUMMARY OF THE INVENTION

In view of the foregoing background, an object of the present invention is to provide an antistatic contact structure which requires less processing steps than that of a conventional antistatic contact, notably within the framework of the production of an integrated circuit comprising floating gate transistors.

This and other objects, advantages and features according to the present invention are provided by an integrated circuit on a silicon substrate comprising at least one polysilicon line and at least one antistatic contact connecting the polysilicon line to the silicon substrate. The antistatic contact may comprise a thin oxide layer between the polysilicon line and the silicon substrate. The thin oxide layer is of a sufficiently small thickness so that a current flows through it by the tunnel effect when the polysilicon line is brought, with respect to the substrate, to a voltage greater or less than determined thresholds.

The antistatic contact may be above a doped region forming with the substrate an NP or PN junction. The thin oxide layer preferably has a thickness between 0.002 and 0.015 micrometers. The integrated circuit may comprises at least one floating gate transistor, and a floating gate thereof may be insulated from the substrate by a tunnel oxide layer also forming the thin oxide layer of the antistatic contact. The integrated circuit may also form an electrically programmable and erasable memory.

Another aspect of the present invention is directed to a method for manufacturing an integrated circuit, including the manufacture of at least one antistatic contact between a polysilicon line and a silicon substrate. The method comprises the steps of growing a first oxide layer on the silicon substrate, providing at least one aperture in the first oxide layer, and growing a second oxide layer at the bottom of the aperture. The method further comprises depositing a polysilicon layer which penetrates the aperture, and etching the polysilicon layer in such a way as to obtain at least one polysilicon line extending above the aperture.

The polysilicon layer may be deposited without removing the second oxide layer at the bottom of the aperture. The second oxide layer is of a sufficiently small thickness so that a current flows through it by the tunnel effect when the polysilicon line is brought, with respect to the substrate, to a voltage greater or less than determined thresholds.

The method may comprise a step for etching the polysilicon layer so as to simultaneously obtain at least one polysilicon line extending above the aperture, and at least one floating gate of a floating gate transistor. The method may comprise a step for implanting dopants into the substrate in a region opposite to the aperture provided in the first oxide layer so as to form an NP or PN junction with respect to the substrate.

### BRIEF DESCRIPTION OF THE DRAWINGS

These objects, features and advantages of the present invention will be discussed in more detail in the following description of an exemplary embodiment of an antistatic contact according to the invention, and of a method for manufacturing such an antistatic contact, with reference to the appended figures wherein:

FIG. 1 is partial sectional view of an integrated circuit comprising an antistatic contact according to the prior art;

FIG. 2 is a partial sectional view of an integrated circuit comprising an antistatic contact according to the present invention;

FIG. 3 is an electrical diagram of the combination of an antistatic contact and an NP junction according to the present invention;

FIGS. 4, 5 and 6 are current-voltage curves illustrating the electrical properties of an antistatic contact according to the present invention;

FIG. 7 is a top view of an integrated circuit comprising an antistatic contact according to the present invention; and

FIGS. 8A-8E illustrate the method steps for manufacturing an integrated circuit according to the present invention.

### DETAILED DESCRIPTION OF THE PREFERRED EMBODIMENTS

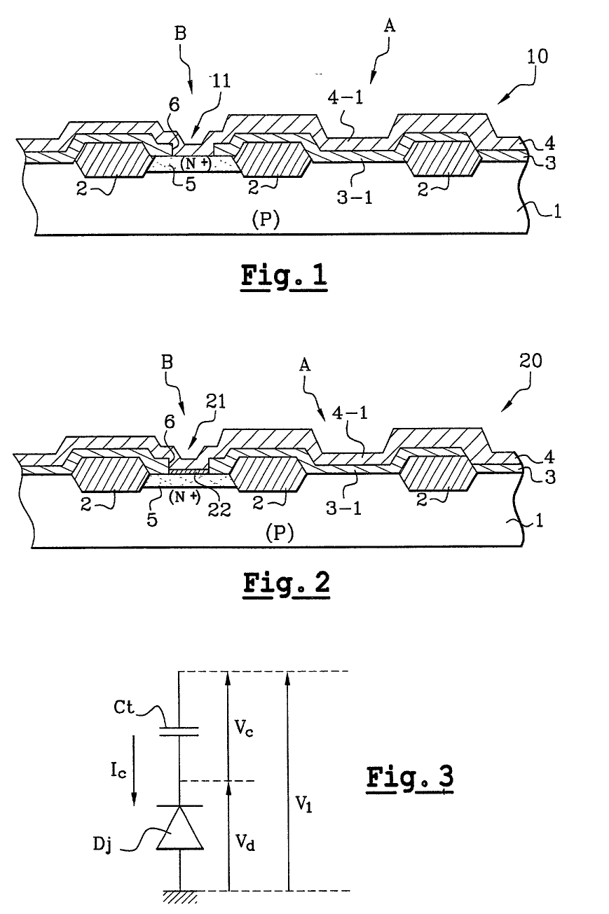

FIG. 2 is a partial sectional view of an integrated circuit 20 comprising an antistatic contact 21 according to the invention. A portion of the integrated circuit illustrated herein is identical to that of FIG. 1, with the same components being designated by the same reference numbers. The integrated circuit 20 includes a P-type substrate 1, field oxide areas 2 separating an active region A and an inactive region B, an oxide layer 3 deposited on the substrate 1, and a polysilicon layer 4 deposited on the oxide layer 3. The oxide layer 3 forms the gate oxide 3-1, and the polysilicon layer forms the gate material 4-1 in the active area A.

The antistatic contact 21 according to the invention, produced in area B, conventionally comprises an aperture 6 provided in the oxide layer 3, into which penetrates the polysilicon 4. According to the invention, the polysilicon 4 is not in contact with the substrate 1 because the antistatic contact 22 comprises a thin oxide layer 22 at the bottom of the aperture 6, which separates the polysilicon 4 from the substrate 1. An N+ doped region 5 forming a PN junction with the remainder of the substrate 1 is conventionally below the oxide layer 22.

According to the invention, the thin oxide layer 22 provides good electrical insulation for the polysilicon layer 4 with respect to the substrate 1 when the polysilicon 4 receives an electrical voltage of a few volts. However, when the voltage increases as a result of the build-up of electrostatic charges in the polysilicon layer 4, the thin oxide layer 22 allows the passage of a discharge current Ic. Such a current Ic occurs by the tunnel effect (Fowler-Nordheim effect) and fits the following relationship:

I_{c}=A*Eox²*e^{e(-B/Eox)} (1)

A and B are constants and Eox is the electric field in the thin oxide 22.

Providing a conventional NP or PN junction under the antistatic layer 21 according to the invention is necessary for protection in the case of a breakdown of the thin oxide layer 22. If such a breakdown occurs, a resistive contact occurs between the polysilicon line 4 and the N+ doped region 5 of the substrate 1. Eventually, an antistatic contact according to the invention, the thin oxide 22 of which has broken down, has substantially the same electrical properties as a conventional antistatic contact.

Such an antistatic contact 21 has various advantages. It is not necessary that the polysilicon layer 4 have the same doping as region 5 because it is insulated from the latter by a thin oxide layer 22. On the other hand, because of the thin oxide layer 22, the dopants in the polysilicon layer 4 do not diffuse into the substrate 1 during the annealing phases and are not added to the dopants present in the region 5. In other words, the localized pollution of the substrate 1 by the diffusion of dopants in the vicinity of the antistatic contact 21 is less than in the prior art. The location to be reserved for the antistatic contact 21 is therefore smaller than in the prior art.

Another advantage of such an antistatic contact is that it is straightforward to obtain within the manufacture of an integrated circuit comprising floating gate transistors, wherein the tunnel oxide layer of the floating gates may be used as a thin oxide layer 22. Before describing this advantage, it will be demonstrated that the combination of the antistatic contact 21 according to the invention and of the NP (or PN) junction formed between region 5 and the substrate allows a current I_{c} to flow when the polysilicon line 4 is submitted to a high electrostatic voltage.

FIG. 3 is the electrical diagram of the combination of an antistatic contact according to the invention and of an NP junction. The antistatic contact is represented by a tunnel capacitor Ct in series with a diode Dj representing the NP junction. Capacitor Ct receives on its anode a voltage V₁, which is considered here as an electrostatic voltage which may appear on the polysilicon line during the manufacturing of an integrated circuit. Diode Dj is reverse-biased, and the cathode of the diode is connected to the cathode of capacitor Ct, and its anode is grounded to the potential of the substrate 1. The voltage on the terminals of the capacitor Ct is designated by V_{c}, and the voltage on the terminals of diode Dj is designated as V_{d}. The sum of voltages V_{c} and V_{d} is equal to voltage V₁ as both components in series form a voltage divider bridge.

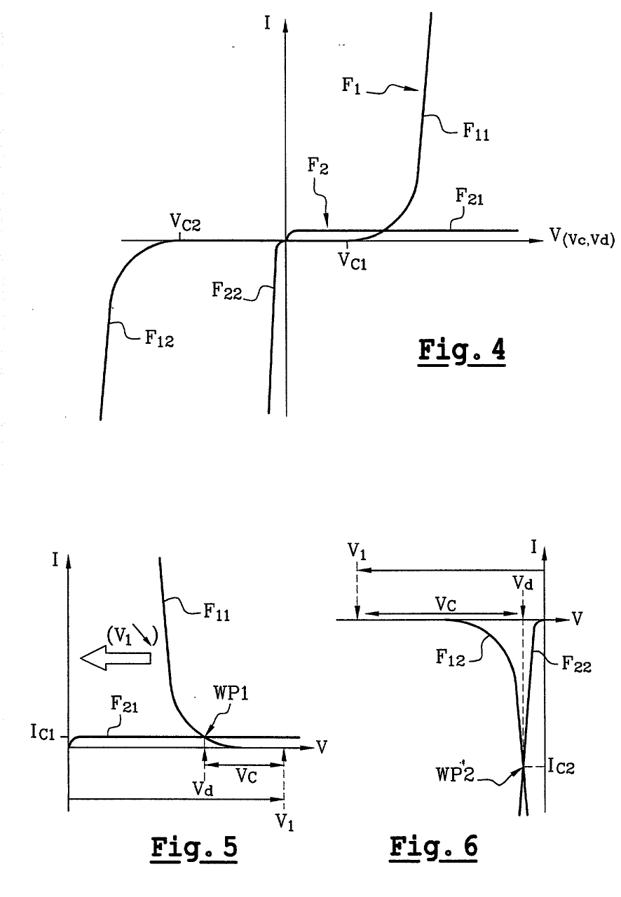

FIG. 4 represents the current/voltage F₁ curve of the tunnel capacitor Ct, which corresponds to the relationship (1) and also represents the current/voltage F₂ curve of diode Dj. Curve F₁ comprises a half-curve F₁₁ for positive voltages, and a half-curve F₁₂ for negative voltages. A current starts to flow across the tunnel capacitor Ct when the voltage V_{c} on its terminal is greater than a positive threshold voltage V_{c1}, or is less than a negative threshold voltage V_{c2}. Moreover, curve F₂ of diode Dj comprises a half-curve F₂₁ for positive voltages (standard current/voltage curve of a reverse-biased diode), and a half-curve F₂₂ for negative voltages (standard current/voltage curve of a forward-biased diode).

To check whether an electrostatic discharge current will flow in the unit formed by the tunnel capacitor Ct and diode Dj, let us first assume that a positive voltage V₁ greater than V_{c1} appears in the polysilicon line. To cause a current to flow, there should be a common operating point between the tunnel capacitor Ct and the diode Dj. To check for the existence of such an operating point, both half-curves F₁₁ and F₂₁ are plotted on a same graph, as illustrated in FIG. 5, corresponding to the quadrant of the positive currents and voltages of FIG. 4.

According to good engineering practices, half-curve F₁₁ is plotted in this quadrant by having it rotate by 180° around the current axis I (V=0), and then shifting it along the voltage axis by a value equal to V₁. It appears that half-curves F₁₁ and F₂₁ intersect at an operating point WP1 corresponding to a current I_{c1}. The existence of such an operating point ensures the flow of electrostatic charges. If voltage V₁ decreases (for example, because of the removal of electrostatic charges) curve F11 moves towards the left hand side of the diagram as illustrated by an arrow. Current I_{c1} remains constant because of the flat shape of curve F₂₁ (leakage current in a reverse-biased diode). If voltage V₁ continues to decrease, curve F₁₁ is outside the quadrant and does not intersect curve F₂₁ any longer, so there is no longer a discharge current I_{c}.

A similar check may be made by assuming that a negative voltage V₁ less than V_{c2} appears in the polysilicon line. To ensure that there is a common operating point, both half-curves F₁₂ and F₂₂ are plotted on a same graph, as illustrated in FIG. 6, corresponding to the quadrant of negative currents and voltages of FIG. 4. Half-curve F₁₂ is plotted by having it rotate by 180° around the current axis I (V=0), then by shifting it along the voltage axis by a value equal to −V₁. Here also, it appears that half-curves F₁₁ and F₂₁ have a common operating point WP2 where they intersect, corresponding to a negative current I_{c2}, which ensures the flow of electrostatic charges. As voltage V₁ increases and approaches zero (for example, because of the removal of electrostatic charges) half-curve F₁₂ moves towards the right hand side of the quadrant and current I_{c2} decreases until it becomes zero.

Eventually, the combination of an antistatic contact according to the invention and an NP or PN junction provides sufficient flow of the electrostatic charges when the voltage V1 appearing in the polysilicon line exceeds a certain threshold V_{cl}, V_{c2}. Moreover, as shown earlier, the assumption of a possible breakdown of the thin oxide of the antistatic contact is not a drawback as the antistatic contact according to the invention then becomes the equivalent of a conventional antistatic contact.

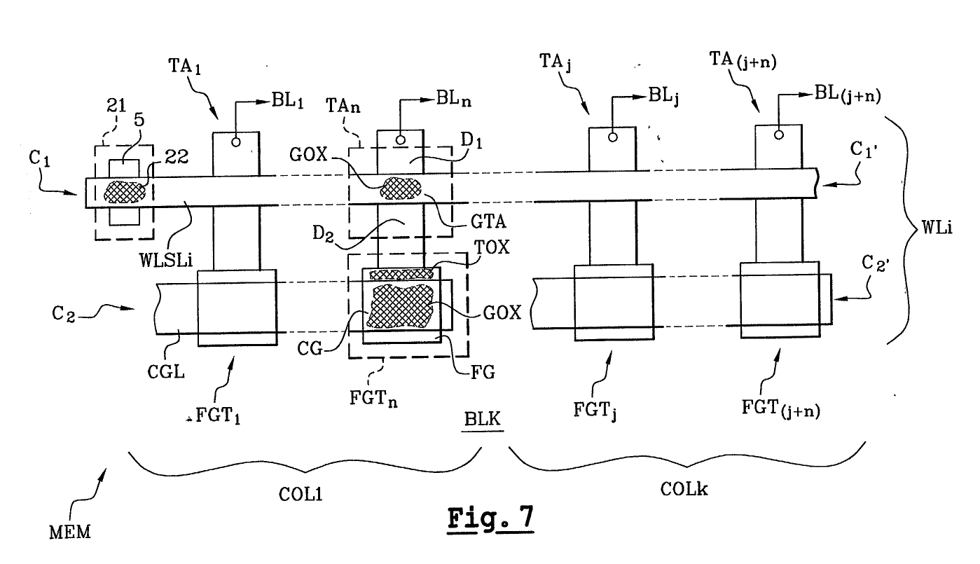

FIG. 7 illustrates an application of the present invention to the protection of polysilicon lines in electrically programmable and erasable memories. FIG. 7 illustrates very schematically, by a top view, the topography of a word line WLi of row i of an electrically programmable and erasable memory MEM. The word line WLi comprises a plurality of floating gate transistors FGT₁-FGTₙ through FGTⱼ-FGT₍ⱼ₊ₙ₎ laid out in columns COL1 through COLk.

Each column comprises n FGT transistors, and each FGT transistor comprises a floating gate FG in polysilicon and a control gate CG. The control gate CG extends above the floating gate FG and is separated from the latter by a gate oxide layer GOX. Floating gate FG extends above a silicon substrate BLK and is separated from the latter by a tunnel oxide layer TOX. The GOX and TOX oxides are marked by hatched lines on the figure, but actually they are under the control gate CG and under the floating gate FG. The control gate CG is a section of a gate control line CGL which passes above the floating gates of all the FGT transistors of a same column.

Each FGT transistor is connected to a bit line BL of the matching row (BL₁-BLₙ through BLⱼ-BL₍ⱼ₊ₙ₎) via an access transistor TA (TA1-Tan through TAj-TA(j+n)). The access transistor TA comprises two doped regions D1, D2 forming the drain and source regions, extending on both sides of a polysilicon gate GTA. A gate oxide GOX is between the gate GTA and the substrate BLK.

In such a memory, the gates GTA of the access transistors TA belonging to the same word line WLi are connected to a common line WLSLi (word line selection line). The WLSLi line is in polysilicon and passes between regions D1 and D2 where it forms the GTA gates of the access transistors TA. Such a line WLSLi has a large length in comparison with the other polysilicon lines as it crosses the entire memory plane horizontally to interconnect the GTA gates of the access transistors. It operates like an antenna in the presence of electric charges, and should be protected against build-up of charges which may damage the gate oxide GOX of the access transistors TA. Thus, an antistatic contact 21 according to the invention is provided at one end of the WLSLi line. It comprises the doped region 5 described earlier, implanted in substrate BLK, and the thin oxide layer 22 extending under the WLSLi line.

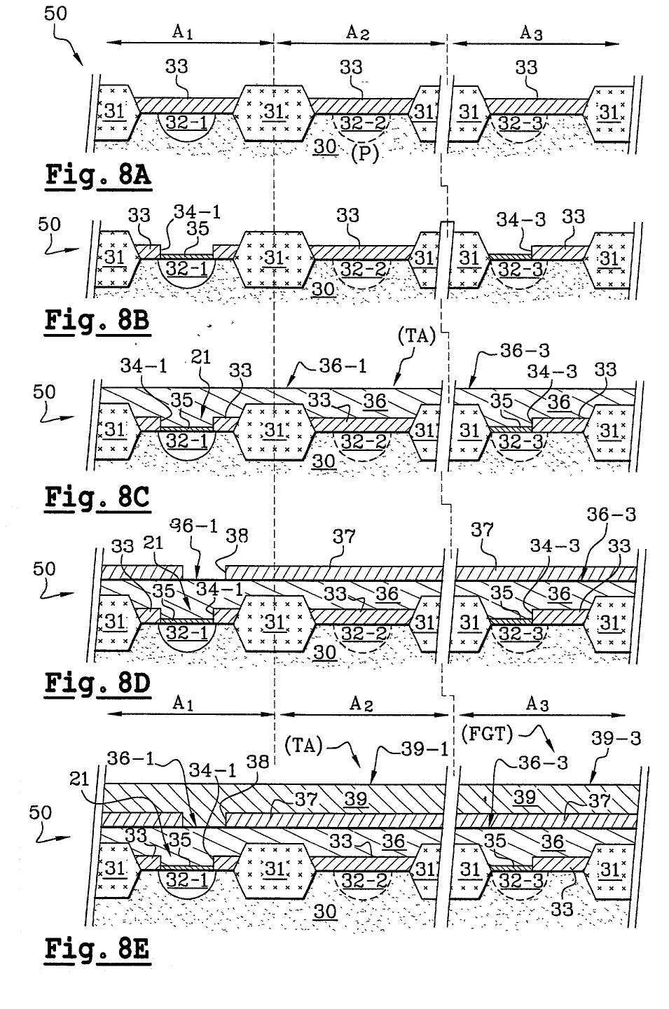

FIGS. 8A-8E are sectional views illustrating the method steps for manufacturing an integrated circuit 50 comprising an antistatic contact according to the invention, and a gate for a floating gate transistor. Each figure has a left hand portion and a right hand portion corresponding to different sectional axes. For example, there is a C₁-C₁′ axis illustrated in FIG. 7 for the left hand portion of each figure, and a sectional axis C₂-C₂′ for the right hand portion of each figure. The thicknesses of the different material layers are not illustrated to scale for better legibility of these figures.

As illustrated in FIG. 8A, regions A₁, A₂, A₃ are delimited at the surface of a silicon substrate 30, here of the P-type, by insulating barriers 31 produced by standard insulating methods (thick oxide, LOCOS, STI . . . ). N+ doped regions 32-1, 32-2, 32-3 are then implanted in the substrate in each of the A₁, A₂, A₃ regions, respectively. Regions 32-2 and 32-3 are illustrated using dotted lines since they are not in the sectional plane, as for example, the D₁ or D₂ region in FIG. 7. A gate oxide layer 33 is then formed on the entire substrate by growing the oxide. For the sake of clarity in the figure, the oxide 33 located on the insulating barriers 31 is not shown.

In the step illustrated in FIG. 8B, apertures 34-1 and 34-3 are provided in the oxide layer 33 in the A₁ and A₃ regions by etching the oxide layer. A tunnel oxide layer 35 is then formed on the substrate by growing the oxide. The tunnel oxide layer 35 is typically of a thickness on the order of 0.002 to 0.015 micrometers according to the manufacturing technology used and the supply voltage which the integrated circuit is expected to receive. The gate oxide layer 33 is of a significantly greater thickness, generally on the order of a few hundredths of micrometers.

For the sake of clarity in the figure, the tunnel oxide 35 formed on the insulating barriers 31 and on the gate oxide layer 33 is not shown, since its thickness is insignificant. Only the tunnel oxide 35 formed at the bottom of apertures 34-1 and 34-3 is illustrated.

In the step illustrated in FIG. 8C, a polysilicon layer 36 is deposited on the whole substrate, then is etched to expose the interconnection lines, the gates of MOS transistors, and the floating gates of the FGT transistors. In particular, a polysilicon line 36-1 is formed in regions A₁ and A₂ and a floating gate 36-3 is formed in region A₃. The polysilicon line 36-1 extends into the aperture 34-1 where it comes into contact with the tunnel oxide 35 extending above the substrate (the doped region 32-1). The whole assembly thereby forms an antistatic contact 21 according to the invention. Thus, during the etching of the polysilicon line 36-1 and the subsequent steps of the manufacturing method, the polysilicon line 36-1 is protected against the building-up of electrostatic charges.

In the step illustrated in FIG. 8D, an insulating layer 37 is formed on the whole substrate, by growing or depositing an oxide or an insulator of the ONO (oxide-nitride-oxide) type. An aperture 38 is then provided in the insulating layer 37 by etching layer 37 above the polysilicon line 36-1.

In the step illustrated in FIG. 8E, a polysilicon 39 is deposited on the insulating layer 37, and is etched to expose interconnection lines and control gates for the floating gate transistors FGT. In particular, a control gate 39-3 is produced above the floating gate 36-3 and a line 39-1 is produced above the line 36-1. Line 39-1 is in contact with line 36-1 by the aperture 38 provided in the insulating layer 37, and is thus connected to the substrate via the antistatic contact 21. This also protects it from build-up of electrostatic charges. Lines 36-1 and 39-1 form, for example, a line for selecting a word line WLSLi of the type described earlier (FIG. 7). Line 36-1 also forms, in the A₂ region and opposite the doped region 32-2, an access transistor TA gate.

Eventually, the manufacture of an antistatic contact according to the invention does not comprise any step for removing the tunnel oxide and is perfectly integrated into the manufacturing process for an integrated circuit, without requiring any further processing step. The aperture 34-1 in the oxide layer 33 is produced at the same time as aperture 34-3, and other apertures of the same type for receiving the floating gates of the FGT transistors.

The production of a conventional antistatic contact would require the removal of the tunnel oxide 35 located at the bottom of aperture 34-1. For this purpose, as an etching mask cannot be directly deposited on the tunnel oxide. First of all, a polysilicon layer should be deposited on the tunnel oxide. The polysilicon layer should then be etched to obtain, facing the aperture 34-1, another aperture forming an etching mask for the tunnel oxide.

That which is claimed is:

1. An integrated circuit (20, 50) on a silicon substrate (1, 30) comprising at least one polysilicon line (4, 36-1, 39-1) and at least one antistatic contact connecting the polysilicon line to the silicon substrate, characterized in that the antistatic contact (21) comprises a thin oxide layer (22, 35) laid out between the polysilicon line and the silicon substrate, the thin oxide layer being of a sufficiently small thickness so that a current (Ic, Ic1, Ic2) flows across it by the tunnel effect when the polysilicon line (4, 36-1, 39-1) is brought, with respect to the substrate, to a voltage (V1) greater or less than a determined threshold (Vc1, Vc2).

2. The integrated circuit according to claim 1, wherein the antistatic contact is laid out above a doped region (5, 32-1) forming with the substrate a NP or PN junction.

3. The integrated circuit according to any of claims 1 and 2, wherein the thin oxide layer has a thickness between 0.002 and 0.015 micrometers.

4. The integrated circuit according to claim 3, comprising at least one transistor (FGT) with a floating gate (36-3).

5. The integrated circuit according to claim 4, wherein the floating gate (36-3) is insulated from the substrate (30) by a tunnel oxide layer (35) also forming the thin oxide layer of the antistatic contact

6. The integrated circuit according to any of claims 1 to 5, forming an electrically programmable and erasable memory (MEM).

7. A method for manufacturing an integrated circuit (50), including the manufacture of at least one antistatic contact between a polysilicon line (36-1) and a silicon substrate (30), comprising the steps:
growing a first oxide layer (33) on the silicon substrate (30),
providing at least an aperture (34-1) in the first oxide layer (33),
growing a second oxide layer (35) at the bottom of the aperture (34-1),
depositing a polysilicon layer (36) which penetrates the aperture (34-1), and
etching the polysilicon layer so as to obtain at least one polysilicon line (36-1) extending above the aperture (34-1),
characterized in that the polysilicon layer (36) is deposited without removing the second oxide layer (35) present at the bottom of the aperture (34-1) beforehand, and in that the second oxide layer (35) is of a sufficiently small thickness so that a current (Ic, Ic1, Ic2) flows across it by the tunnel effect when the polysilicon line (36-1) is brought, with respect to the substrate, to a voltage (V1) greater or less than a determined threshold (Vc1, Vc2).

8. The method according to claim 7, comprising a step for etching the polysilicon layer so as to simultaneously obtain at least one polysilicon line (36-1) extending above the aperture (34-1) and at least one floating gate (36-3) of a floating gate transistor.

9. The method according to any of claims 7 and 8, comprising a step for implanting dopants into the substrate, in a region (32-1) located facing the aperture (34-1) provided in the first oxide layer (33), in order to form a PN or NP junction with respect to the substrate.

10. The method according to any of claims 7 to 9, wherein the integrated circuit (50) is an electrically programmable and erasable (MEM) memory.
